(19) United States
(12) Patent Application Publication
(10) Pub. No.: US 2011/0085227 A1
(43) Pub. Date: Apr. 14, 2011

(54) APPEARANCE-MODIFYING DEVICE, METHOD FOR MANUFACTURING SUCH A DEVICE, AND METHOD FOR OPERATING SUCH A DEVICE

(75) Inventors: Alwin Rogier Martijn Verschueren, Eindhoven (NL); Gerrit Oversluizen, Eindhoven (NL); Thomas Caspar Kraan, Eindhoven (NL); Sander Jurgen Roosendaal, Brno (CZ)

(73) Assignee: KONINKLIJKE PHILIPS ELECTRONICS N.V., EINDHOVEN (NL)

(21) Appl. No.: 12/996,407

(22) PCT Filed: Jun. 9, 2009
(86) PCT No.: PCT/IB2009/052436

§ 371 Date: Dec. 6, 2010

(30) Foreign Application Priority Data
Jun. 17, 2008 (EP) 08158384.1

(51) Int. Cl. G02F 1/167; B32B 37/16; H05K 13/00

(52) U.S. Cl. 359/296; 156/145; 216/17; 29/592.1

(57) ABSTRACT

A method for manufacturing an appearance-modifying device (2, 6, 9; 10; 30), for modifying the visual appearance of a surface covered thereby is disclosed. The method comprises the steps of: providing a first substrate (11) having, on a first side thereof, a first electrode layer (17) covered by a dielectric layer (21); providing a second substrate (12) opposite the first side of the first substrate (11); arranging a spacer structure (13) between the first (11) and second (12) substrates to form a plurality of-cells (15, 16; 31) in such a way that an area occupied by each cell includes a portion of the first electrode layer (17); providing a second electrode (18) spaced apart from the first electrode layer (17) at least by the dielectric layer (21), forming, in each of the cells (15, 16; 31), a recess in the dielectric layer (21); and providing, in each of the cells(15, 16; 31), an optically transparent fluid (19) having a plurality of particles (20) dispersed therein.

### FIELD OF THE INVENTION

The present invention relates to a method for manufacturing an appearance-modifying device. It also relates to an appearance-modifying device, and to a method for operating such an appearance-modifying device.

### BACKGROUND OF THE INVENTION

For many types of products, customizable appearance of the product may be desirable. For example, it may be attractive to be able to customize the appearance of at least a part of a product depending on its current state, to convey information about the current state of the product to a user in an intuitive and attractive way. It may also be perceived as attractive to the user of a product to be able to alter its appearance to reflect the user's personality or mood etc.

According to one well-known example, such customizable appearance of a product is realized by exchangeable “skins” on consumer electronic products, such as mobile telephones. This type of “skins” is typically provided as plastic shells that can be exchanged by the user of the product.

It has also been suggested to use electrically controllable optical properties of an appearance-modifying device covering a surface of a product to alter the appearance of the product.

US 2004/0189591 discloses one example of such an appearance-modifying device in the form of electrophoretic display devices covering control buttons of a programmable remote control unit. Depending on the component to be controlled through the programmable remote control unit, the electrophoretic display devices are adjusted to display the settings relevant to the particular component to be controlled.

The appearance-modifying device disclosed in US 2004/0189591 is provided in the form of microcapsules sandwiched between top and bottom electrode layers. Each microcapsule contains positively charged white pigment chips and negatively charged black pigment chips suspended in a clear suspension medium. By forming a suitable electric field pattern in the appearance-modifying device of US 2004/0189591, a black and white image can be formed, which is thus attributed to the respective button.

Although enabling modification of the appearance of a product, more specifically a programmable remote control, the appearance-modifying device disclosed in US 2004/0189591 is not suitable for every application. In particular, the type of appearance-modifying device described above cannot be used when the surface covered thereby itself conveys information. For example, at least a portion of the surface may be a display that is only sometimes active, but then must be clearly visible to the user of the product. Further, the appearance-modifying device of US 2004/0189591 requires a relatively high drive voltage, typically between 5 to 15 V.

### SUMMARY OF THE INVENTION

In view of the above-mentioned and other drawbacks of the prior art, a general object of the present invention is to provide an improved appearance-modifying device, a method for manufacturing such an appearance-modifying device, and a method for operating the appearance-modifying device.

According to a first aspect of the present invention, these and other objects are achieved through a method for manufacturing an appearance-modifying device, for modifying the visual appearance of a surface covered thereby, comprising the steps of: providing a first substrate having, on a first side thereof, a first electrode layer covered by a dielectric layer; providing a second substrate opposite the first side of the first substrate; arranging a spacer structure between the first and second substrates to form a plurality of cells in such a way that an area occupied by each cell includes a portion of the first electrode layer; providing a second electrode spaced apart from the first electrode layer at least by the dielectric layer, forming, in each of the cells, a recess in the dielectric layer; and providing, in each of the cells, an optically transparent fluid having a plurality of particles dispersed therein.

It should be noted that none of the methods according to the various aspects of the present invention is limited to performing the steps thereof in any particular order. Furthermore, some steps may be performed at one point in time, and other steps at another point in time.

In the present application, “fluid” is understood to be a substance, which alters its shape in response to any force and tends to flow or to conform to the outline of the chamber in which it may be contained. The term “fluid” thus includes gases, liquids, vapors and mixtures of solids and liquids, when these mixtures are capable of flow.

The term “particles” is not limited to solid particles, but also includes liquid droplets and fluid-filled capsules.

Either or both of the first and the second substrate may typically be provided as a sheet, which may be more or less flexible. Suitable substrate materials include, for example, glass, polycarbonate, polyimide etc.

Furthermore, at least one of the first and second substrates should be transparent to enable a viewer to see the optical properties of the particles when these are dispersed in the fluid.

By an “optically transparent” medium is, in the present context, meant a medium, which permits passage of at least a fraction of the light (electromagnetic radiation in the visible spectrum) impinging on it.

The present invention is based on the realization that an appearance-modifying device for modifying the appearance of a surface covered thereby can advantageously be achieved using so-called in-plane switching of an electrophoretic device.

The present inventors have further realized that such an appearance-modifying device can advantageously be manufactured by covering the first electrode layer with a dielectric layer, and then forming a recess in the dielectric layer, which minimizes the need for patterning and alignment of the first electrode.

The recess should be provided in such a way that the first electrode layer is exposed, or at least only covered by a very thin remaining layer of dielectric, the condition for the thickness of the remaining layer in relation to the cell being given by the following expression:

$$\frac{{thickness}_{dielectricopening}}{{conductivity}_{dielectric}} ≪ \frac{{radius}_{cell}}{{conductivity}_{fluid}} ≪ \frac{{thickness}_{dielectric}}{{conductivity}_{dielectric}}$$

Providing a recess in the dielectric layer in such a way that the above condition is satisfied results in an electric field configuration in the cell, when a voltage is applied between the first and second electrodes, which efficiently concentrates the particles dispersed in the fluid to a first particle concentration site constituted by the recess (typically exposing a portion of the first electrode layer) and/or to a second particle concentration site constituted determined by the configuration of the second electrode. In this way no further control electrodes are needed to concentrate the particles to a small part of each cell, whereby a ratio between a controllable area in each cell and the total area of the cell can be maximized. In addition, the manufacturing is simplified since fewer layers, and accordingly less alignment is needed in comparison to prior art.

By providing a recess in the dielectric layer, the electric field in the cell can be controlled through the position and configuration of the recess as well as through the electric properties (notably the conductivity) of the dielectric layer. By selecting a dielectric layer having a conductivity that is lower than the conductivity of the fluid in the cell, the electric field can be shaped to efficiently direct the particles towards the first particle concentration site constituted by the recess (typically exposing a portion of the first electrode) when a suitable voltage is applied between the first and second electrodes.

Which position in the cell of the recess in the dielectric that is the most desirable depends on the application of the appearance-modifying device. For some applications, it may be advantageous to have the recesses centrally located in each cell, while other applications may benefit from off-center locations or a mix of some cells having centrally located recesses and other cells having off-center recesses.

The first electrode and the dielectric layer may be transparent, enabling transparent cell properties in the states when the particles are concentrated to at least one of the particle concentration sites (adjacent to at least one of the electrodes). A transparent state may be beneficial if, for example, the surface covered by the appearance-modifying device conveys information.

To achieve such transparent properties, the first electrode may be made of a transparent materials, such as a transparent conducting film, e.g. ITO, IZO or similar, and the dielectric layer may be made of a transparent dielectric material, such as silicon-oxide, silicon nitride or any other suitable transparent dielectric known in the art.

The spacer structure may be provided as a periodic or non-periodic pattern.

To reduce Moiré effects, furthermore, the spacer structure may advantageously be non-rectangular, for example a hexagonal pattern or a non-repeating Penrose tiling, forming cells to contain the fluid.

According to one embodiment, the second electrode may be provided on the dielectric layer on the first side of the first substrate. Hereby, the second substrate can be arranged essentially without alignment

According to another embodiment, the second electrode may be comprised in the spacer structure and be provided together with the spacer structure. At least a portion of the spacer structure may constitute the second electrode. Providing a conductive spacer structure may facilitate the manufacturing, since both the spacer structure and the second electrode are provided at the same time.

According to yet another embodiment, the second electrode may be preformed on the second substrate and the step of providing the second substrate may comprise the steps of aligning the second electrode to be laterally offset in relation to the recess in the dielectric layer; and attaching the second substrate to the first substrate.

Although typically requiring a more accurate alignment than in the case when both the first and second electrode are arranged on the first substrate, or when providing conductive walls, a more robust appearance-modifying device may be achieved, since the provision of the second electrode on the second substrate reduces the sensitivity of the appearance-modifying device to the occurrence of pinholes or other defects in the dielectric layer.

In this embodiment, the spacer structure may advantageously be pre-formed on the second substrate, which is expected to improve the alignment tolerance when providing the second substrate.

Furthermore, the step of forming the recess in the dielectric layer may advantageously comprise the steps of: directing a first material removing beam in such a direction that the spacer structure prevents the first material removing beam from hitting the dielectric layer outside a first segment of the cell; directing a second material removing beam in such a direction that the spacer structure prevents the second material removing beam from hitting the dielectric layer outside a second segment of the cell, different from the first segment and overlapping the first segment in an area of the cell corresponding to the portion of the dielectric layer.

The first and second material removing beam may for example, as in the case of dry etching be streams of ions, such as a plasma of nitrogen or chlorine, bombarding the dielectric material to remove material from the portion of the dielectric layer. By etching from at least two oblique angles, the spacer structure serves as a shadow mask shadowing a first portion of the dielectric layer from the first beam, and a second portion of the dielectric layer from the second beam, within each cell. It is thus possible to control that a central portion of the dielectric layer in the cell, where the first and second segments overlap, is removed more than the rest of the dielectric layer. Hereby, a controllable portion of the first electrode may be exposed, by means of self-alignment, using the spacer structure as a shadow mask, and no additional alignment steps of masks are required. This enables a simplified and cost-efficient manufacturing process.

It should be noted that many other types of material removing beams may be feasible, such as laser beams for laser ablation, water jets for water jet cutting, particle beams for mechanical abrasion etc.

The first material removing beam and the second material removing beam may hit the dielectric material simultaneously, for example originating from two different sources, or sequentially, by means of for example a rotating etcher.

Moreover, the step of forming the recess in the dielectric layer may be performed in a reel-to-reel process. The first substrate and the spacer structure may form different angles in relation to a single material removing beam source at different times, or two or more material removing beam sources may form different angles in relation to the first substrate and the spacer structure.

Moreover, in an area corresponding to each cell, a plurality of recesses may be formed in the dielectric layer.

Having a plurality of recesses, preferably being openings formed in the dielectric layer to expose corresponding portions of the first electrode, in each cell is particularly advantageous in applications where the second electrode is provided on the second substrate. To ensure that the particles move laterally when taken from the dispersed state to a state in which they are concentrated adjacent to at least one of the electrodes, a lateral component of the electric field in the cell is required. Therefore, the second substrate should advantageously be arranged in such a way that an overlap between a particle concentration site(s) on the first substrate and a particle concentration site(s) on the second substrate is prevented. By particle concentration site should be understood a location where particles concentrate when an appropriate voltage is applied.

To prevent such an overlap, an alignment step is typically required. By providing several openings in the dielectric layer covering the first electrode layer, several particle concentration sites are provided on the first substrate. Hereby, the alignment tolerance is improved.

According to a second aspect of the present invention the above-mentioned and other objects are achieved by an appearance-modifying device, for modifying the appearance of a surface covered thereby, comprising: a first substrate having a first electrode layer arranged on a first side thereof, the first electrode layer being covered by a dielectric layer; a second substrate, arranged opposite the first side of the first substrate; a spacer structure spacing apart the first and second substrates in such a way that a space between the first and second substrates is divided into a plurality of cells; in each cell, an optically transparent fluid having a plurality of particles dispersed therein, the particles being moveable in the fluid through application of an electric field; and a second electrode spaced apart from the first electrode layer at least by the dielectric layer, wherein the dielectric layer, in each cell, has a recess formed therein to expose a corresponding portion of the first electrode layer; and wherein the distribution of particles within each of the cells is controllable, by application of a voltage between the electrodes, from a first, dispersed state, to a second state in which the particles are concentrated adjacent to at least one of the recess in the dielectric layer and the second electrode.

It should be noted that the particles dispersed in the fluid may or may not be charged. For uncharged particles, the particles may be caused to move in response to the application of an electric field through dielectrophoresis, which is described in detail in “Dielectrophoresis; the behavior of neutral matter in non-uniform electric fields”, by H. A. Pohl, University Press, Cambridge, 1978.

In the case of charged particles, the majority of the particles may advantageously have the same sign charge so as to prevent clustering of oppositely charged particles. (Electrical neutrality of the fluid is ensured by the presence of ions of opposite charge).

However, it may also be advantageous to provide the particles as a mix of positively and negatively charged particles. The particles may then be collected at both electrodes, depending on polarity.

The particles may, furthermore, be essentially uniformly distributed in the absence of an electric field. When a field is applied, the particles may be re-distributed. Either the particles move until the field is removed or a state is entered in which there is an equilibrium between the forces exerted on the particles through their own charges (in the case of electrophoresis) or dipoles (in the case of dielectrophoresis) and the applied electric field. For a more detailed description of electrophoresis, the following document is referred to:

“Principles of Colloid and Surface Chemistry”, by P. C. Hiemenz and R. Rajagopalan, 3^{rd} edition, Marcel Dekker Inc., New York, 1997, pp. 534-574.

The first and second electrode may be arranged to simultaneously control a plurality of cells. Hereby, controlling of an appearance-modifying device between different states may be performed in an easy manner, using a single control voltage to switch a plurality of cells simultaneously. Furthermore, the fraction of the total area of the appearance-modifying device that can be evacuated from particles can hereby be achieved, because space can be saved that would otherwise have been needed to accommodate further electrodes passing between cells on their way to other cells to be controlled thereby. This is particularly advantageous for applications in which it is desirable that the appearance modifying device be controllable to a transparent state, such as when the surface to be covered by the appearance modifying device itself conveys information. This may, for example, be the case when the device to be covered is a display device or similar.

In one embodiment of the appearance-modifying device according to the present invention, the particles may comprise a first set of negatively charged particles and a second set of positively charged particles.

With two differently charged sets of particles, more states can be achieved, especially since the different sets of particles advantageously have different optical properties. One set of particles may for example be of one color while the other set of particles may be of another color.

With no electrical field applied both the negatively and positively charged particles may disperse throughout the cell providing an optical appearance being an outcome from the combination of both negatively and positively charged particles.

According to a third aspect of the present invention, the above-mentioned and other objects are achieved by a method for operating an appearance-modifying device comprising a plurality of cells, each comprising a plurality of charged particles having a first polarity distributed in an optically transparent fluid, and first and second electrodes for enabling laterally displacing the particles to concentrate the particles at a first and/or a second particle concentration site through application of a voltage between the first and second electrodes, the first particle concentration site having a larger particle concentration area than the second particle concentration site, the method comprising the steps of: determining a voltage between the first and second electrodes resulting in an electric field configured to concentrate the particles at the first particle concentration site; and applying the voltage between the first and second electrodes to concentrate the particles at the first particle concentration site. By “particle concentration site” should be understood a site in the cell where the particles concentrate upon application of a voltage between the first and second electrodes. Particles having a given polarity (positive or negative charge) will typically move towards the first or the second particle concentration site depending on the polarity (positive or negative) of the voltage. The locations in the cell of the first and second particle concentration sites are determined by the electric field configuration resulting in the cell from application of a voltage between the first and the second electrode. This electric field configuration may, for example, be determined by the electrode configuration and the configuration of other structures in the cell etc. For the appearance-modifying device according to the second aspect of the present invention, the location of the first particle location site is, for example, largely determined by the electrical properties of the dielectric layer and the fluid in the cell.

By “particle concentration area” should be understood the area across which the particles concentrated at a particle concentration site can be distributed. For a particle concentration site having a small particle concentration area, a high physical concentration of particles, in terms of number of particles per unit volume, may be obtained for a given number of particles. For a particle concentration site having a large particle concentration area, the same number of particles may result in a much lower physical concentration of particles.

The present inventors have realized that this asymmetry in particle concentration area between the first and the second particle concentration site can be used to achieve fast switching between a state in which the particles are dispersed and a state in which the particles are concentrated at a particle concentration site. In particular, the present aspect of the invention is based on the realization that fast switching can be achieved by determining and applying a voltage being such that the particles are driven towards the second particle concentration site having the larger particle concentration area.

Because of the larger particle concentration area, the charged particles concentrated at the second particle concentration site will have a smaller (reducing) effect on the electric field adjacent to the second particle concentration site than for the same number of particles concentrated at the, smaller, first particle concentration site.

Each cell may advantageously be defined by first and second substrates and a spacer structure sandwiched between the first and second substrates; and the first electrode is provided as a first electrode layer formed on the first substrate, and the first particle concentration site is defined by an opening formed in the dielectric layer, exposing a portion of the first electrode layer; and the second electrode is separated from the first electrode layer at least by the dielectric layer, the second particle concentration site being determined by the second electrode.

By configuring the appearance-modifying device in this manner, the desired asymmetric configuration with respect to particle concentration area of the respective particle concentration sites may be achieved in an advantageous manner, through the manufacturing method according to the first aspect of the present invention.

Further variations and effects of the third aspect of the present invention are largely analogous to those of the first and second aspects described above.

According to a fourth aspect of the present invention, the above-mentioned and other objects are achieved by a method for operating an appearance-modifying device comprising a plurality of cells, each comprising a plurality of particles including a first set of charged particles having a first color and a first polarity and a second set of charged particles having a second color and a second polarity, opposite the first polarity, distributed in an optically transparent fluid, and first and second electrodes for enabling laterally displacing the particles to concentrate the particles at a first and/or a second particle concentration site through application of a voltage between the first and second electrodes, wherein the cell is configured in such a way that application between the first and second electrodes of a given voltage results in a first electric field adjacent to the first particle concentration site and a second electric field adjacent to the second particle concentration site, the first electric field having a higher field strength than the second electric field, the method comprising the steps of: determining a polarity and a magnitude of the voltage between the first and second electrodes resulting in that the first electric field is sufficiently strong to concentrate the first set of charged particles to the first electrode, and that the second electric field is so weak that the second set of particles substantially remain in a dispersed state; and applying the determined voltage between the first and second electrodes to thereby control the cell to a state having substantially the second color.

The present inventors have further realized that an asymmetry in cell configuration can be used to achieve several color states using only a single pair of electrodes in each cell. By selecting properties (polarity and magnitude) of a voltage between the first and the second electrode that result in an electric field configuration that is capable of driving particles of one polarity towards the first particle concentrations site, but that is substantially not capable of driving particles of the opposite polarity towards the second particle concentration site, a single set of particles can be controlled selectively using only the first and the second electrode.

Based upon this realization, the cells comprised in the appearance-modifying device can be controlled to four different color states: a first state in which all particles are dispersed in the fluid; a second state in which the first set of particles are concentrated at the first particle concentration site and the second set of particles are dispersed in the fluid; a third state in which the second set of particles are concentrated at the first particle concentration site and the first set of particles are dispersed in the fluid; and, finally, a fourth state in which the first set of particles are concentrated at the first particle concentration site and the second set of particles are concentrated at the second particle concentration site, or vice versa.

Each cell may advantageously be defined by first and second substrates and a spacer structure sandwiched between the first and second substrates; and the first electrode is provided as a first electrode layer formed on the first substrate, and the first particle concentration site is defined by a recess formed in the dielectric layer; and the second electrode is separated from the first electrode layer at least by the dielectric layer, the second particle concentration site being determined by the second electrode.

By configuring the appearance-modifying device in this manner, the desired asymmetric electric field configuration may be achieved in an advantageous manner, through the manufacturing method according to the first aspect of the present invention.

Further variations and effects of the fourth aspect of the present invention are largely analogous to those of the first, second and third aspects described above.

### BRIEF DESCRIPTION OF THE DRAWINGS

These and other aspects of the present invention will now be described in more detail, with reference to the appended drawings showing currently preferred embodiments of the invention, wherein:

FIGS. 1a-g schematically illustrate various applications for embodiments of the appearance-modifying device according to the present invention;

FIGS. 2a-c are perspective views of an exemplary appearance-modifying device according to an embodiment of the present invention;

FIGS. 3a-b are cross-section views of the appearance-modifying device of FIG. 2 taken along the line A-A, illustrating a configuration of the appearance-modifying device;

FIGS. 4a-b are cross-section views of the appearance-modifying device of FIG. 2 taken along the line A-A, illustrating a first exemplary configuration of the appearance-modifying device;

FIGS. 5a-b are cross-section views of the appearance-modifying device of FIG. 2 taken along the line A-A, illustrating a second exemplary configuration of the appearance-modifying device;

FIG. 6 is a flow chart schematically illustrating a first exemplary method for manufacturing an appearance-modifying device according to an embodiment of the present invention;

FIGS. 7a-f schematically illustrate the appearance-modifying device manufactured according to the method of FIG. 6 in states following the corresponding method steps;

FIGS. 8a-c schematically illustrate the step of removing a portion of the dielectric layer of the method illustrated in FIG. 6;

FIG. 9 is a flow chart schematically illustrating a second exemplary method for manufacturing an appearance-modifying device according to an embodiment of the present invention;

FIGS. 10a-f schematically illustrate the appearance-modifying device manufactured according to the method of FIG. 9 in states following the corresponding method steps;

FIG. 11 is a schematic cross-section view illustrating the electrical field in a cell of an appearance modifying device according to an embodiment of the present invention;

FIGS. 12a-c are cross-section views illustrating fast switching between states of an appearance-modifying device according to an embodiment of the invention; and

FIGS. 13a-e schematically illustrate different color states of an appearance-modifying device according to another embodiment of the present invention.

### DETAILED DESCRIPTION OF PREFERRED EMBODIMENTS

The present invention will be mainly described hereinafter with reference to an in-plane electrophoretic appearance-modifying device having the first electrode exposed in an opening in the dielectric layer of each cell, and the second electrode being a part of the spacer structure forming the cells, the cells being simultaneously controlled.

It should be noted that this by no means limits the scope of the invention, which is equally applicable to in-plane electrophoretic appearance-modifying devices having other electrode configurations, such as having a plurality of openings exposing the first electrode in each cell, the second electrode being provided separately from the spacer structure and/or structures enabling individual control of each cell.

Further, the present invention is mainly described with reference to an appearance-modifying device controllable to a transparent state, although the scope of the invention also includes appearance-modifying devices that are not controllable to a transparent state, such as, for example appearance-modifying devices having a non-transparent first or second substrate, which may have other optical properties, such as colors or structures, in itself.

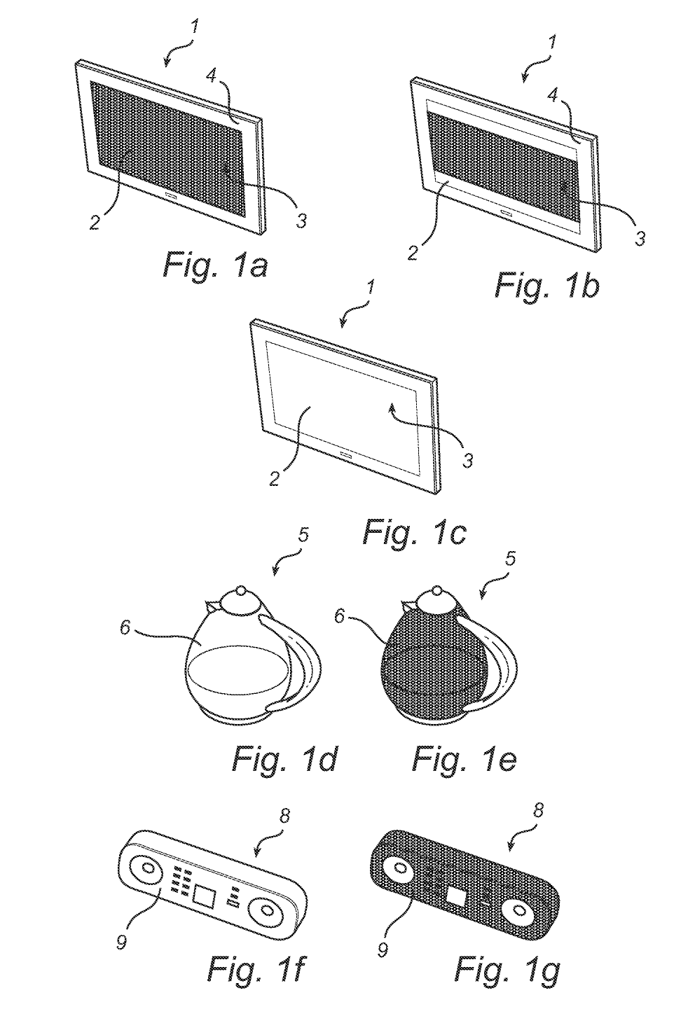

There are a large number of applications for various embodiments of the appearance-modifying device according to the present invention, some of which are schematically illustrated in FIGS. 1a-g.

In FIGS. 1a-c, a flat screen television device 1 is provided with an appearance-modifying device 2 covering at least the display 3 of the television device 1.

FIG. 1a shows the television device 2 in normal, full-screen operation in which the entire display is used for displaying image content, with the appearance-modifying device 2 in its transparent state. Accordingly, the entire display 3 of the television device 1 is visible for a viewer.

FIG. 1b shows the television device 1 in wide-screen operation with the appearance-modifying device 2 in a partially transparent state such that a portion of the display 3 has had its appearance modified by the appearance-modifying device 2. In the present example, the appearance-modifying device 2 has modified the portion of the display 3 that is not used to display image content to have essentially the same appearance as the frame 4 surrounding the display 3.

Finally, FIG. 1c shows the television device 1 when turned off, with the appearance-modifying device 2 in a state in which it modifies the entire display 3 to have essentially the same appearance as the frame 4 surrounding the display 3.

A further application in the form of a water boiler 5 is schematically illustrated in FIGS. 1d-e. By covering the water boiler 5 by an appearance-modifying device 6, the water boiler can be made to visually illustrate to a user in which state it is. For example, the appearance-modifying device 6 can be controlled between a first color, for instance blue, to indicate that the water in the water boiler is cold and a second color, for instance red, to indicate that the water (and thus the water boiler 6) is hot. Alternatively, in accordance with another embodiment of the present invention the water boiler 6 may be controlled between, say, a transparent state and three different colors to indicate four different states of the water boiler 6, for example transparent, blue, red and finally black when the water is boiled.

In another application, in the form of the music player 8 in FIGS. 1f-g, the music player 8 can be covered by an appearance-modifying device 9 to enable a user to control the appearance, such as the color, of the music-player according to her/his mood or personal preference. Alternatively, in accordance to another embodiment of the present invention the music player 8 can be covered by an appearance-modifying device 9 which in controllable between four different appearances, such as four different colors.

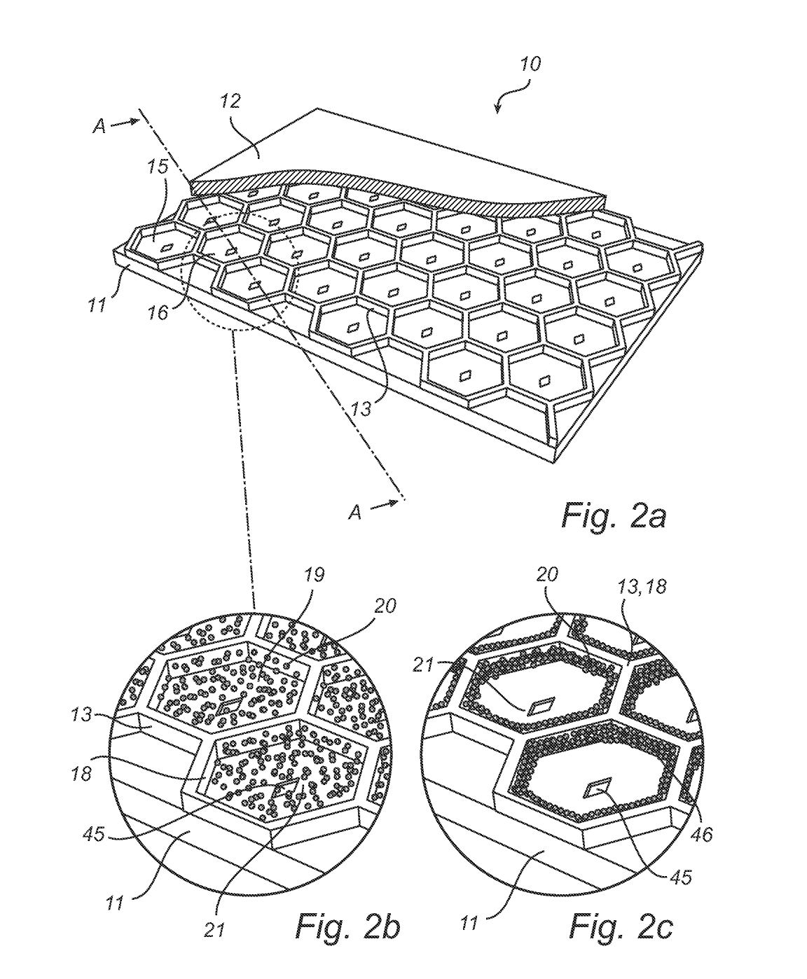

Having now indicated some of the numerous applications for an appearance-modifying device, an exemplary embodiment of the appearance-modifying device according to the present invention will be described below with reference to FIGS. 2a-c.

FIG. 2a schematically illustrates an appearance-modifying device 10 comprising first 11 and second 12 oppositely arranged transparent substrates. The substrates 11, 12 are spaced apart by a spacer structure 13 in such a way that the space between the first 11 and second 12 substrates is divided into a plurality of cells 15, 16 forming a hexagonal pattern. (only two cells are indicated by reference numerals in FIG. 2a).

Referring to FIG. 2b, each cell 15, 16 is filled with an optically transparent fluid 19 and a plurality of particles 20 (only one representative particle is indicated in FIG. 2b). Furthermore, to control the cells 15, 16, a first electrode layer 17 (not shown in FIGS. 2a-c) is arranged on the first substrate 11, and a second electrode 18 is comprised in the spacer structure 13 (in the exemplary embodiment illustrated in FIGS. 2a-c, the spacer structure 13 is conductive). The first electrode layer 17 is covered by a dielectric layer, apart from being exposed in openings formed in the dielectric layer 21, as is illustrated in FIGS. 2b-c. Each such opening constitutes a first particle concentration site 45, to which particles 20 may concentrate when an appropriate voltage is applied between the first 17 and the second 18 electrodes.

In FIG. 2b, the cells 15, 16 are in a state in which the particles 20 are dispersed in the fluid 19 so that the appearance of the surface covered by the cells 15, 16 is determined by the optical properties of the particles 20. Typically, the particles 20 are in the dispersed state when there is no voltage difference between the first 17 and second 18 electrodes.

Turning now to FIG. 2c, the particles 20 in the cells 15, 16 have been concentrated to a second particle concentration site 46 determined by the second electrode 18, i.e. the walls of the cells, through application of a suitable voltage between the first 17 and second 18 electrodes. Through the concentration of particles 20 in the cells 15, 16, the cells 15, 16 are switched to a state in which the optical properties of the appearance-modifying device 10 are not determined by the particles, but by the first 11 and second 12 substrates, any further layers, such as the first electrode layer 17, the dielectric layer 21 and/or color filters etc that may be included in the appearance-modifying device 10 (although not included in FIGS. 2a-c). In the presently illustrated exemplary case, the cells 15, 16 are, in FIG. 2c, in the transparent state and, hence, do not modify the appearance of a surface covered thereby (other than absorbing and/or reflecting some of the light leading to a decreased brightness of the underlying surface).

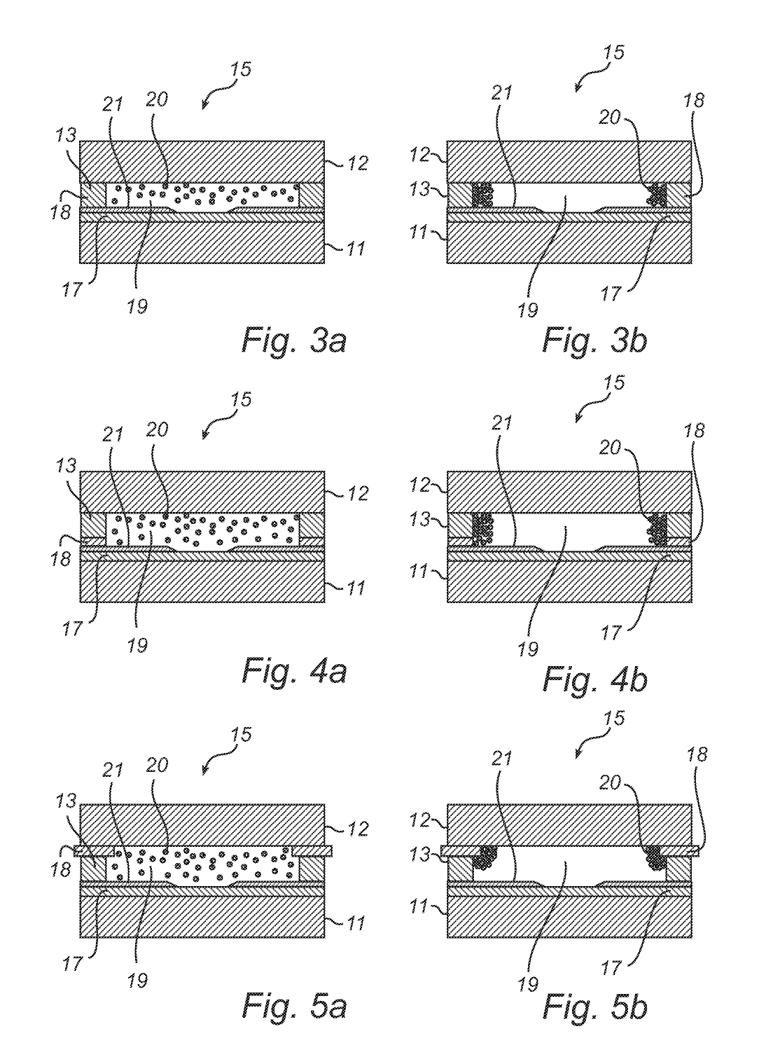

The appearance-modifying device 10 in FIGS. 2a-c can be configured in various ways, some of which will be described below with reference to FIGS. 3a-b to 5a-b.

In FIGS. 3a-b to 5a-b the same reference numeral as for FIGS. 2b-c are used since the corresponding cells along the line A-A are controlled by the same electrodes and are in the same states as the cells of FIGS. 2b-c.

In FIG. 3a, which is a schematic cross-section view of the appearance-modifying device 10 in FIG. 2a taken along the line A-A, a first exemplary configuration of the cell 15 is schematically illustrated.

As can be seen in FIG. 3a, the particles 20 in the cell 15 are controlled to be in a state in which they are dispersed in the fluid 19. In FIG. 3b the particles 20 in the cell 15 are controlled to be in a state in which they are concentrated adjacent to the second electrode 18. The configuration of FIGS. 3a-b corresponds to that shown in FIG. 2a-c.

In FIG. 4a-b the same states are shown as in FIG. 3a-b. In FIG. 4a-b, which schematically show a second exemplary configuration of the cell 15 it can be seen that the second electrode 18 is covered by the spacer structure 13 along the perimeter of the cell 15. Through this configuration, the particles 20 can concentrate close to the part of the cell wall, which is close to the first substrate, as illustrated in FIG. 4b.

Turning now to FIGS. 5a-b, the same states are shown as in FIGS. 3a-b, but a third exemplary configuration is schematically illustrated in which the second electrode 17 is formed on the second substrate 12. The second electrode 18 has a pattern that substantially corresponds to the pattern of the spacer structure 13 and is essentially aligned to the spacer structure 13. Here, the second electrode 18 is only partly shielded by the walls. Through this configuration, the particles 20 can concentrate close to the part of the cell wall, which is close to the second substrate 12, as illustrated in FIG. 5b.

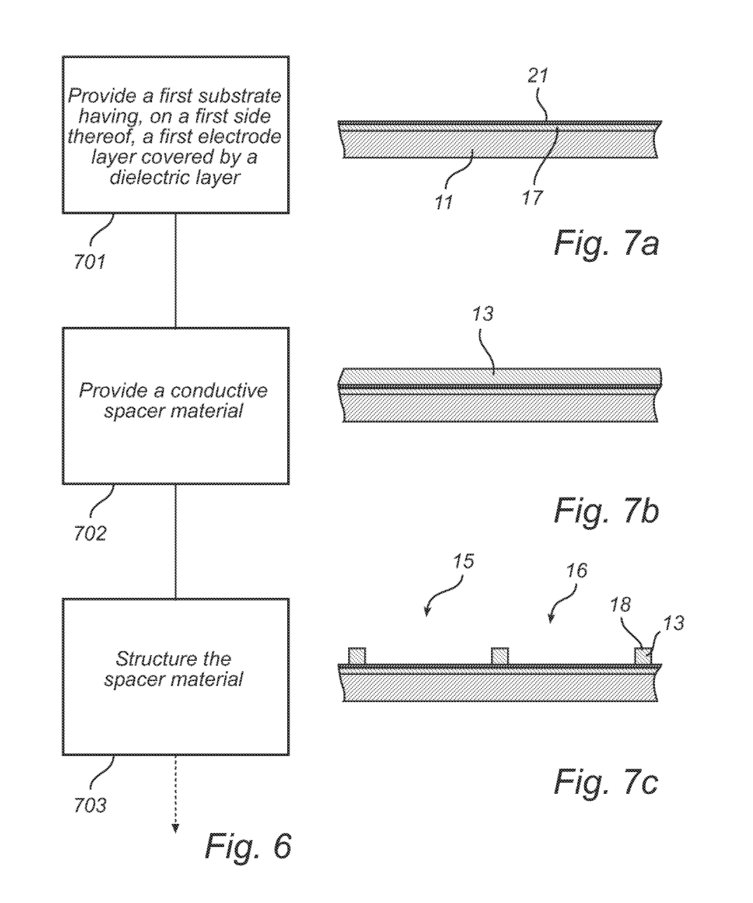

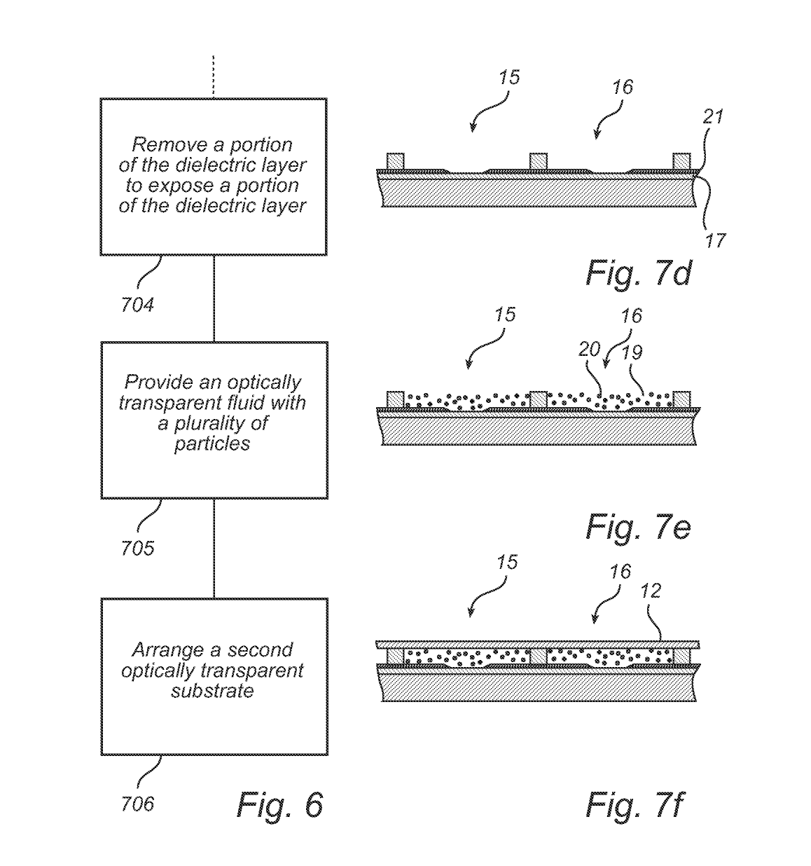

An example of an appearance-modifying device according to the present invention and a method for manufacturing such an appearance-modifying device will now be described with reference to FIG. 6 which is a flow chart schematically illustrating such a method and FIGS. 7a-f which schematically illustrate the appearance-modifying device in states following the corresponding method steps of FIG. 6. In FIG. 6 the same reference numerals as for FIGS. 2b-c are used.

In a first step 701 a first substrate 11 having, on a first side thereof, a first electrode layer 17 covered by a dielectric layer 21, is provided.

In a subsequent step 702 a conductive spacer material 13 is provided on the dielectric layer 21.

In the next step 703 the spacer material 13 is structured, for example through embossing, to form a plurality of cells on the first side of the first substrate 11. At the same time, the second electrode 18 is provided in form of the spacer structure 13.

The spacer material may be provided using any conventional manufacturing technology, such as through any reel-to-reel coating techniques that are able to form a thin layer. Examples of such techniques include slot-die, where coating liquid is forced out from a reservoir through a slot by gravity or under pressure, and transferred to a moving substrate, and gravure coating, where an engraved roller runs in a coating bath that fills the imprinted dots or lines of the roller with the coating material, whereafter the excess coating on the roller is removed by the doctor blade and the coating is deposited onto the substrate as it passes through the engraved roller and a pressure roller. The structuring of the spacer material may, for example, be performed through of embossing, which is typically accomplished with a combination of heat and pressure on the material. This is achieved by using a metal die usually made of brass and a counter die that fit together and actually squeeze the fibers of the material. The pressure and a combination of heat “irons” while raising the level of the structure. Other structuring techniques may be photolithography, micro-molding or laser ablation. Alternatively, the spacer structure may be provided directly through various printing techniques, such as gravure, flexo, offset, screen, or inkjet printing.

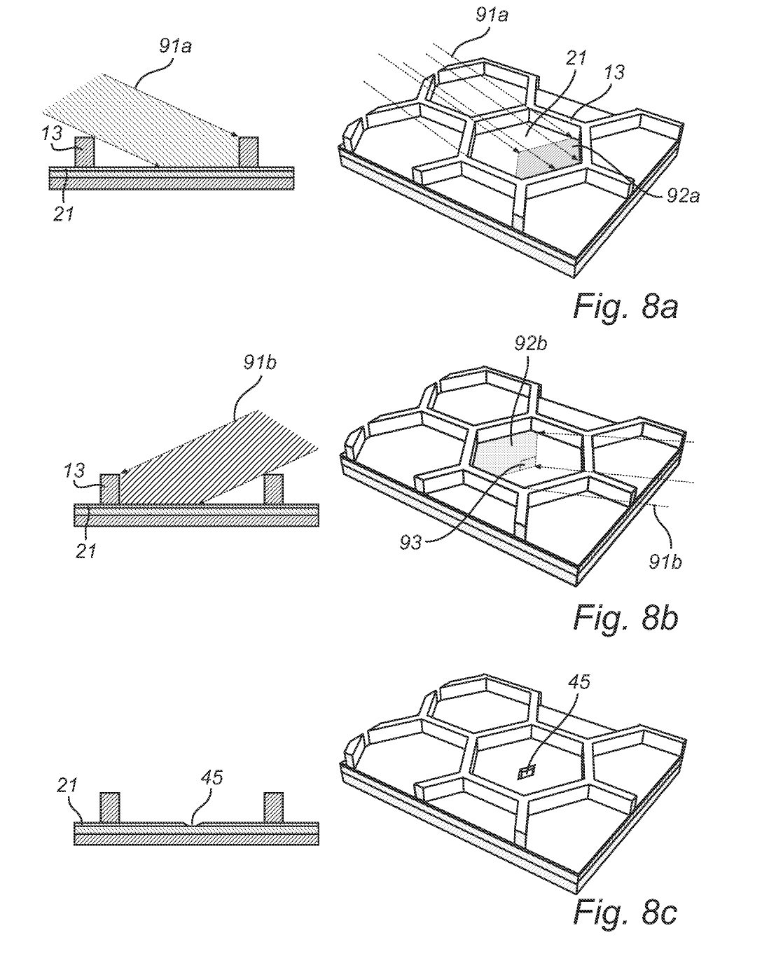

Thereafter, in step 704, a portion of the dielectric layer 21 centrally located in each cell is removed to expose a corresponding portions of the first electrode 17. The removal of the dielectric layer 21 may be performed using any suitable method known in the art. A preferred method for removing the portion of the dielectric layer will, however, be described below in connection with FIG. 8.

In a following step 705 each cell 15, 16 is filled with a fluid-particle suspension including a plurality of particles 20 suspended in an optically transparent fluid 19.

As a final step 706 a second optically transparent substrate 12 is arranged on the opposite side of the spacer structure 13 from the first substrate 11, to close the cell.

In FIG. 8 the steps of a preferred method for removing a portion of the dielectric layer 21 in each cell 15-16 is illustrated.

As shown in FIG. 8a, a first material removing beam 91a is directed in a first direction, indicated by the arrows in FIG. 8a, towards the cells 15, 16. The first material removing beam 91 a hits a first portion 92a of the dielectric layer 21 in the cell, since the spacer structure 13 act as a mask to prevent the first material removing beam 91a from hitting a remaining portion of the dielectric layer.

Subsequently, as shown in FIG. 8b, a second material removing beam 91b is directed in a second direction, indicated by the arrows in FIG. 8b, towards the cells 15, 16. The second material removing beam 91b hits a second portion 92b of the dielectric layer 21 in the cell, since the spacer structure 13 acts as a mask to prevent the second material removing beam 91b from hitting a remaining portion of the dielectric layer. In FIGS. 8a-b the two beams 91a-b are shown to hit the cells 15, 16 sequentially, but they may also hit the cells 15, 16 simultaneously.

In this manner the portion 93 of the dielectric layer where both the first material removing beam 91a and the second material removing beam 91b hit the dielectric layer 21, in other words where the portions 92a and 92b coincide, the dielectric layer 21 is removed more than in the remaining area of the cell, creating an opening in the dielectric layer 21 to expose the first electrode 17.

The result is illustrated in FIG. 8c where an opening 45 in the dielectric layer 21 is created, exposing the first electrode 17.

Advantageously, the above-described method for removing a portion of the dielectric layer 21 may be performed using dry-etching, in which case the material removing beams 91a-b are ion beams. Alternatively, the portion of the dielectric layer 21 may be removed using laser ablation or similar, in which case the material removing beams 91a-b are laser beams.

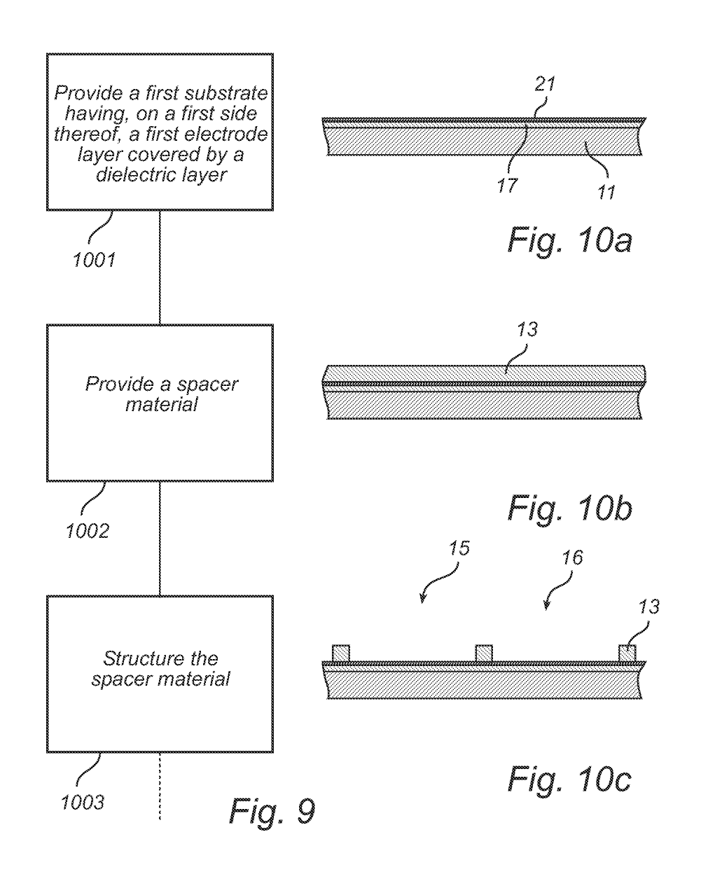

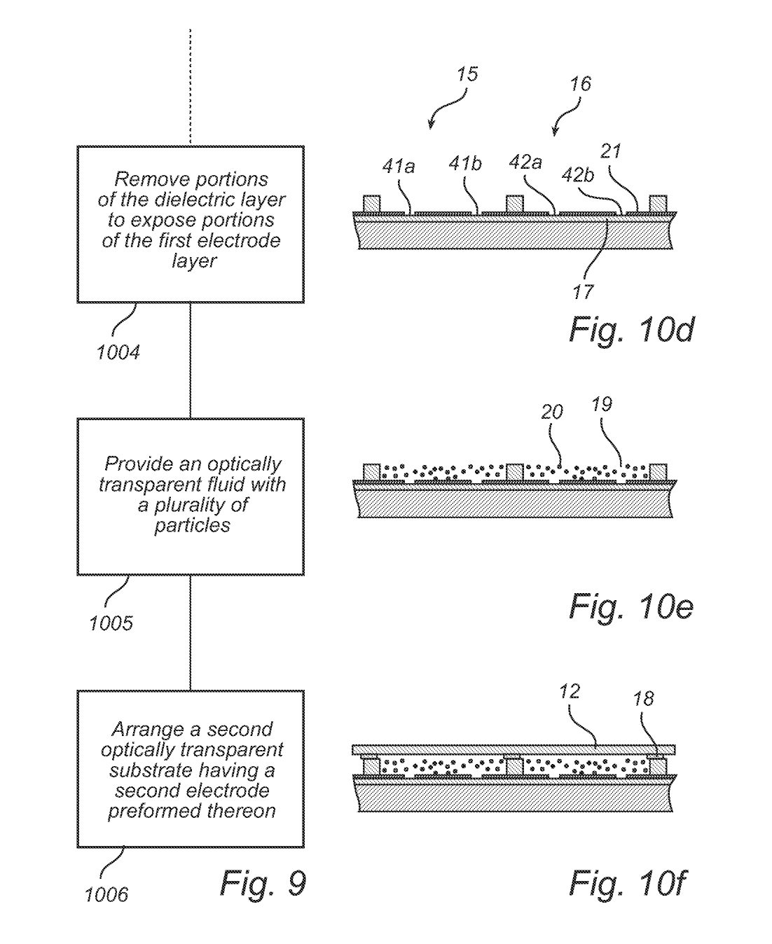

Another example of an appearance-modifying device 10 according to the present invention and a method for manufacturing such an appearance-modifying device 10 will now be described with reference to FIG. 9 which is a flow chart schematically illustrating such a method and FIGS. 10a-f which schematically illustrate the appearance-modifying device in states following the corresponding method steps of FIG. 9.

In a first step 1001 a first substrate 11 having, on a first side thereof, a first electrode layer 17 covered by a dielectric layer 21, is provided.

In a subsequent step 1002 a spacer material 13 is provided on the dielectric layer 21.

In the next step 1003 the spacer material is structured, for example through embossing, to form a plurality of cells 15, 16 on the first side of the first substrate 11.

Thereafter, in step 1004, a plurality of portions 41a-b, 42a-b of the dielectric layer 21 in the cells 15, 16 are removed to expose corresponding portions of the first electrode 17. The removal of the dielectric layer 21 may, for example, be performed through laser ablation. Although only two portions 41a-b, 42a-b per cell 15, 16 are indicated in the cross-section views of FIGS. 10d-f, it should be understood that each cell may include further exposed portions of the first electrode layer 17.

In a following step 1005, the cells 15, 16 are filled with a fluid-particle suspension including a plurality of particles 20 suspended in an optically transparent fluid 19.

As a final step 1006 a second optically transparent substrate 12 with a second electrode 18 formed thereon is arranged on the opposite side of the spacer structure 13 from the first substrate 11, to close the cell.

As can be seen in FIG. 10f, the second electrode 18 may not be perfectly aligned to the spacer structure 13. By providing several openings in the dielectric layer 21 covering the first electrode layer 17, several particle concentration sites are provided. This prevents an overlap between particle concentration sites on the first substrate 11 and particle concentration sites on the second substrate 12. Hereby, the alignment tolerance is improved.

Furthermore, the tolerance to bending and deformation of the appearance-modifying device 10 may be improved by each of the measures of providing the second electrode on the second substrate and providing several openings in the dielectric layer in each cell. This is an important feature of an appearance-modifying device 10, which should advantageously be capable of conforming to the shape of the device or object to be covered thereby.

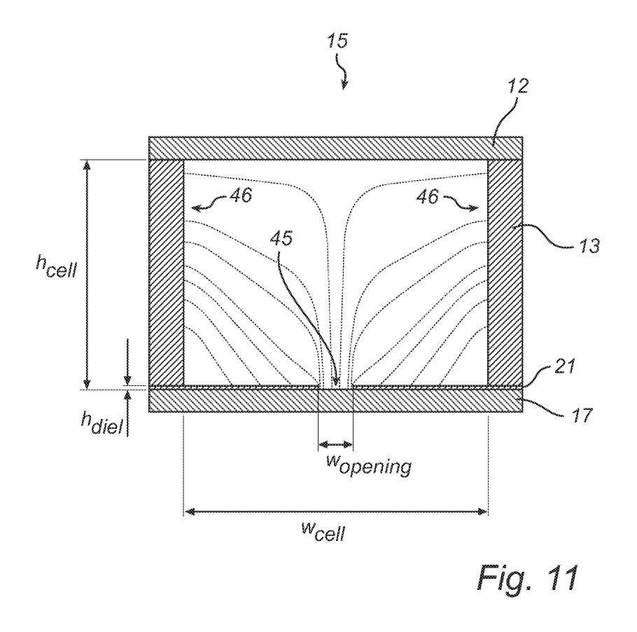

In FIG. 11 the electric field in a cell having one opening in the dielectric layer 21 exposing the first electrode 17 is illustrated. In the presently illustrated example, the second electrode 18 is comprised in the spacer structure 13. As can be seen in FIG. 11, depending on the polarity of the particles 20 in the cell 15 and the polarity of the voltage applied between the first 17 and second 18 electrodes, the particles 20 will concentrate at a first particle concentration site 45 at the opening in the dielectric layer 21 and/or the second particle concentration site 46 at the cell wall formed by the spacer structure 13.

Also apparent from FIG. 11 is that the particle concentration area of the first particle concentration site 45 is considerably smaller than the particle concentration area of the second particle concentration site 46.

Furthermore, studying the electric field lines in FIG. 11, the skilled person will realize that, for a given voltage between the first 17 and second 18 electrodes, the electric field adjacent to the first particle concentration site 45 will be considerably stronger than the electric field adjacent to the second particle concentration site 46.

It should be noted that the cell 15 in FIG. 11 is not drawn to scale, but has had its vertical proportions exaggerated for illustration purposes. Typical dimensions and potentials, using the notation in FIG. 11 would be:

w_{cell=}150 μm;

h_{cell=}10 μm;

h_{diel=}100 nm;

w_{opening=}10 μm;

V_{first electrode}=0V;

V_{second electrode}=5 V.

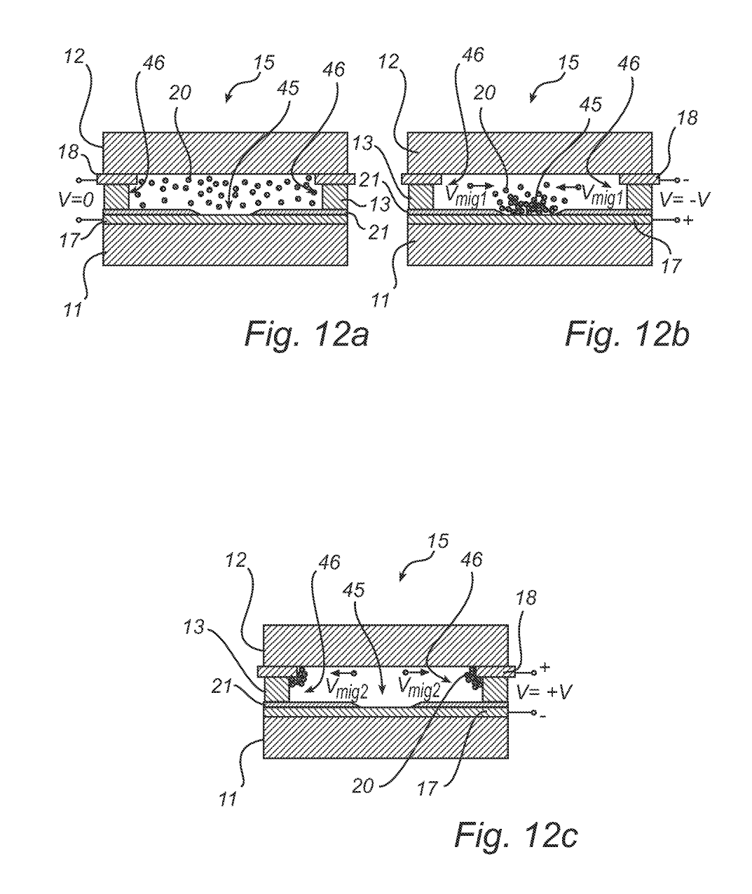

In the following, a method for fast switching of the cells 15, 16 of an appearance-modifying device according to an embodiments of the present invention will be described with reference to FIGS. 12a-c, that schematically illustrate one exemplary cell 15 in two different appearance-modifying states.

In the example illustrated in FIGS. 12a-c, the appearance-modifying device corresponds to that described above in connection with FIGS. 5a-b, where the second electrode 18 is formed on the second substrate 12. In the presently illustrated example, the particles 20 are negatively charged.

In the state illustrated in FIG. 12a, there is no voltage applied between the first 17 and second 18 electrodes, and there is, accordingly, no electrical field present in the cell 15. Therefore, the particles 20 are dispersed within the cell 15, and the optical properties of the surface covered by at least this part of the appearance-modifying device are determined by the optical properties of the particles 20.

When desiring to switch the cell 15 in FIG. 12a from the state illustrated therein to a state in which the optical properties of the surface covered by the appearance-modifying device are no longer determined by the particles 20, but by the properties of the surface itself or by the properties of the other structures in the cell 15, such as the first substrate 11, the first electrode 17, the dielectric layer 21 and/or any color filter or colored reflector (not shown in FIGS. 12a-b) depending on application, at least the following options are available:

1. Concentrate the particles 20 to the first particle concentration site 45; or

2. concentrate the particles 20 to the second particle concentration site 46.

In FIG. 12b, which schematically illustrates the first option above, a negative voltage −V has been applied (meaning that the electrical potential of the first electrode 17 is higher than the electrical potential of the second electrode 18). Due to this negative voltage, an electrical field is formed in the cell 15, which concentrates the particles 20 to the first particle concentration site 45. Because of the considerably smaller particle concentration area of the first particle concentration site 45 (the opening in the dielectric layer 21 compared to the area around the second electrode 18 along the entire perimeter of the cell 15), the physical concentration of particles 20 at the first particle concentration site 45 becomes high, leading to a clustering of negatively charged particles there. This cluster shields the first electrode 17 and counteracts the electric field, leading to a considerably reduced velocity of particles 20 moving towards the first particle concentration site 45 as is schematically illustrated in FIG. 12b by the migration velocity v_{mig1}.

The situation illustrated in FIG. 12b will now be compared with option 2 above, which is schematically illustrated in FIG. 12c.

In the cell 15 illustrated in FIG. 12c, a positive voltage +V has instead been applied (same magnitude, but opposite polarity with respect to −V in FIG. 12b), which leads to the migration of the negatively charged particles 20 towards the second particle concentration site 46 along the perimeter of the cell 15. Due to the larger particle concentration area of the second particle concentration site 46, the physical concentration of particles at the second particle concentration site 46 becomes considerably lower than was the case in FIG. 12b. After a while, this lead to a much smaller reduction in the migration velocity V_{mig2} of particles 20 moving towards the second particle concentration site 46.

As is evident to the person skilled in the art, the migration velocities vmig1, vmig2 of particles 20 moving towards the first 45 and second 46 particle concentration sites, respectively, are not constant, but are determined by such factors as the electrical field strength, the particle charge and the mobility of the particles 20 in the fluid 19. In the situations illustrated in FIGS. 12b-c, the migration velocity will initially be higher when the particles 20 move towards the first particle concentration site 45 (as in FIG. 12b) than when the particles 20 move towards the second particle concentration site 46 (as in FIG. 12c), since the electrical field in the vicinity of the first particle concentration site 45 in FIG. 12b is initially higher than the electrical field in the vicinity of the second particle concentration site 46 in FIG. 12c. When, however, a sufficient number of particles 20 have been concentrated to the respective particle concentration sites 45, 46, the migration velocity V_{mig2} in FIG. 12c will be higher than the migration velocity V_{mig1} in FIG. 12b.

In addition to the method for fast switching described above in connection with FIGS. 12a-c, the asymmetric electrode configuration of the cells 15, 16 in the appearance-modifying device can be used to achieve four different states using only the first 17 and the second 18 electrode.

To achieve these additional states, the asymmetric electric field configuration described above in connection with FIG. 11 may be used in an appearance-modifying device in which the plurality of particles 20 include a first set 20a of charged particles having a first polarity and a first color, and a second set 20b of charged particles having a second, opposite polarity and a second color.

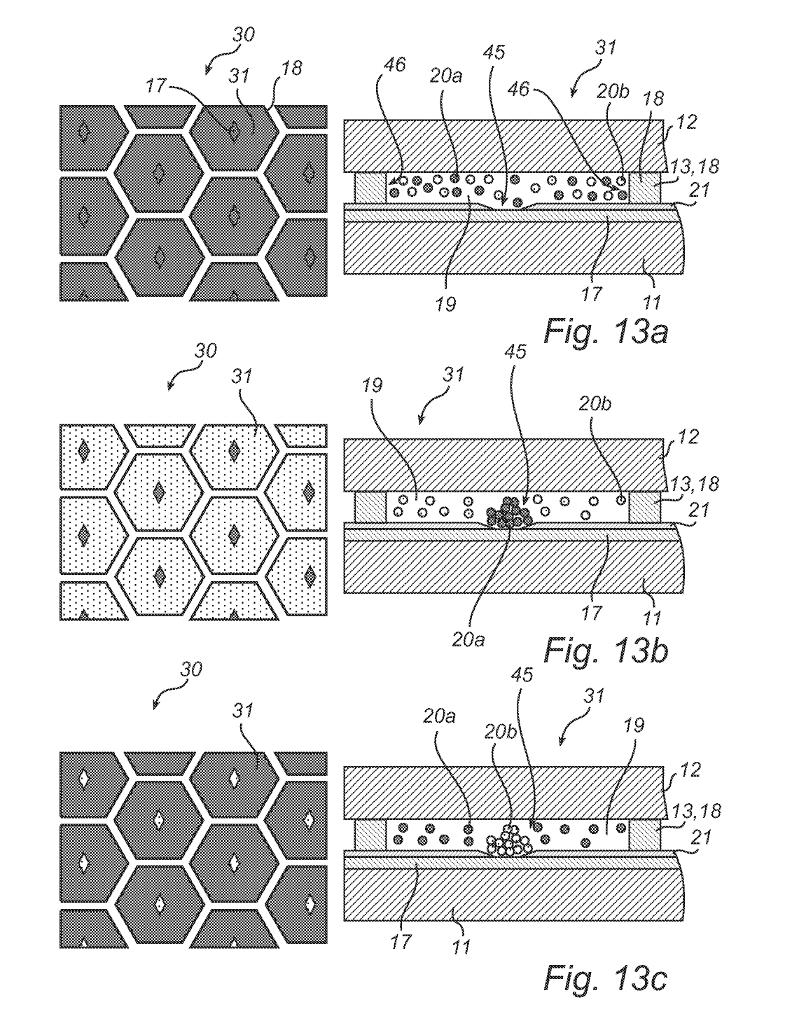

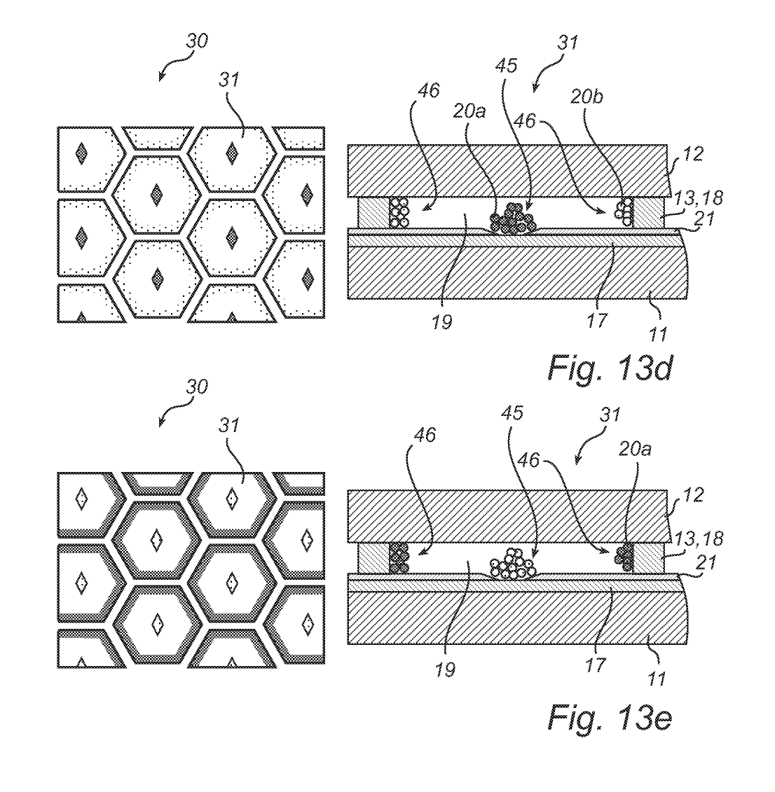

An exemplary embodiment of such a multi-color appearance-modifying device 30 will now be described with reference to FIGS. 13a-e, showing plane views and cross-section views of a cell 31. The appearance-modifying device 30 in FIGS. 13a-e is similar to the appearance-modifying device of FIG. 2a-c, except in that the particles 20 are here provided as a mix of positively 20a and negatively 20b charged particles, the positively charged particles 20a having one color, such as cyan, and the negatively charged particles 20b having another color, such as orange. Parts equivalent of those in FIG. 2 are denoted by the same numerals.

A mixed color state is illustrated in FIG. 13a. When no electrical field is applied between the first electrode 17 and the second electrode 18, all particles are dispersed within the cell. The optical appearance is here a combination of the two particles 20a, 20b, in this example green color, as a mixture of cyan and orange.

A first color state is illustrated in FIG. 13b. When a sufficient positive potential difference is applied between the first electrode 17 and the second electrode 18, the positively charged particles concentrate adjacent to the stronger electrical field (see also FIG. 11) close to the first particle concentration site 45, while the negatively charged particles are attracted to the second particle concentration site 46. The electrical field strength at the second particle concentration site 46 (the perimeter of the cell 31), is smaller than at the first electrode particle concentration site 45 (the opening in the dielectric layer 21 exposing the first electrode 17), resulting in that the negatively charged particles 20b are not affected as much by the field and remain dispersed in the cell. Accordingly, the negatively charged particles 20b will affect the optical appearance of the appearance-modifying device 30, here, orange color.

A second color state is illustrated in FIG. 13c. When a sufficient negative potential difference is applied between the first electrode 17 and the second electrode 18, the negatively charged particles 20b concentrate at the first particle concentration site 45 due to the stronger electrical field close to the first particle concentration site 45, while the positively charged particles 20a are attracted to the second particle concentration site 46. As described above in connection with FIG. 13a, the electrical field strength near the second particle concentration site 46, is smaller than at the first particle concentration site 45, resulting in that the positively charged particles 20a are not affected as much and remain dispersed in the cell. Accordingly, the positively charged particles 20a will affect the optical appearance of the appearance-modifying device 30, here, cyan color.

Controlling of the appearance-modifying device 30 to the states where the particles concentrate at different electrodes, depending on polarity, is illustrated in FIG. 13d-e, resulting in a color state that is not determined by the particles, but rather by the other parts of the appearance-modifying device 30. In particular, the state illustrated in FIGS. 13d-e will be a transparent state if the cell itself has transparent properties.

In FIG. 13d the transparent state is achieved when a sufficiently high positive potential difference is applied between the first electrode 17 and the second electrode 18 for the positively charged particles 20a to concentrate at the first particle concentration site 45, and for the negatively charged particles 20b to concentrate at the second particle concentration site 46.

In FIG. 13e the transparent state is achieved when a sufficiently high negative potential difference is applied between the first electrode 17 and the second electrode 18 for the negatively charged particles 20b to concentrate at the first particle concentration site 45, and for the positively charged particles 20a to concentrate at the second particle concentration site 46.

The person skilled in the art realizes that the present invention is by no means limited to the preferred embodiments. For example, many other electrode configurations, other than those described herein, are feasible, such as the electrodes or other control means being provided on different substrates. Furthermore, the spacer structure may advantageously be pre-formed on the second substrate.

1. A method for manufacturing an appearance-modifying device (2, 6, 9; 10; 30), for modifying the visual appearance of a surface covered thereby, comprising the steps of:
providing a first substrate (11) having, on a first side thereof, a first electrode layer (17) covered by a dielectric layer (21);
providing a second substrate (12) opposite the first side of the first substrate (11);
arranging a spacer structure (13) between the first (11) and second (12) substrates to form a plurality of cells (15, 16; 31) in such a way that an area occupied by each cell includes a portion of the first electrode layer (17);
providing a second electrode (18) spaced apart from the first electrode layer (17) at least by the dielectric layer (21),
forming, in each of the cells (15, 16; 31), a recess in the dielectric layer (21); and
providing, in each of the cells (15, 16; 31), an optically transparent fluid (19) having a plurality of particles (20) dispersed therein.

2. The method according to claim 1, wherein the spacer structure (13) is provided on the first side of the first substrate (11), and the step of forming the recess comprises locally removing a portion of the dielectric layer 21.

3. The method according to claim 2, wherein the step of forming the recess in the dielectric layer (21) comprises the steps of:
directing a first material removing beam (91a) in such a direction that the spacer structure (13) prevents the first material removing beam (91a) from hitting the dielectric layer (21) outside a first segment (92a) of the cell (15, 16; 31);
directing a second material removing beam (91b) in such a direction that the spacer structure (13) prevents the second material removing beam (91b) from hitting the dielectric layer (21) outside a second segment (92b) of the cell (15, 16; 31), different from the first segment (92a) and overlapping the first segment (92a) in an area of the cell corresponding to the portion of the dielectric layer (21).

4. The method according to claim 1, wherein the second electrode (17) is preformed on the second substrate (12) and the step of providing the second optically transparent substrate (12) comprises the steps of:
aligning the second electrode (18) to be laterally off-set in relation to the recess in the dielectric layer (21); and
attaching the second substrate (12) to the first substrate (11).

5. An appearance-modifying device (10; 30), for modifying the appearance of a surface covered thereby, comprising:
a first substrate (11) having a first electrode layer (17) arranged on a first side thereof, the first electrode layer (17) being covered by a dielectric layer (21);
a second substrate (12), arranged opposite the first side of the first substrate (11);
a spacer structure (13) spacing apart the first (11) and second substrates (12) in such a way that a space between the first (11) and second (12) substrates is divided into a plurality of cells (15, 16: 31);
in each cell (15, 16: 31), an optically transparent fluid (19) having a plurality of particles (20) dispersed therein, the particles (20) being moveable in the fluid (19) through application of an electric field; and
a second electrode (18) spaced apart from the first electrode (17) layer at least by the dielectric layer (21),
wherein the dielectric layer (21), in each cell (15, 16: 31), has a recess formed therein; and
wherein the distribution of particles (20) within each of the cells (15, 16: 31) is controllable, by application of a voltage between the electrodes (17, 18), from a first, dispersed state, to a second state in which the particles (20) are concentrated adjacent to at least one of the recess in the dielectric layer (21) and the second electrode (18).

6. The appearance-modifying device according to claim 5 wherein the second electrode (18) is arranged on the dielectric layer (21) on the first side of the first substrate (11).

7. The appearance-modifying device according to claim 5, wherein at least a portion of the spacer structure (13) is conductive and forms the second electrode (18).

8. The appearance-modifying device according to claim 5, wherein the second electrode (18) is preformed on the second substrate (12).

9. The appearance-modifying device (10; 30) according to claim 5, wherein the dielectric layer (21), in each cell (15, 16: 31), has at least two recesses formed therein.

10. A method for operating an appearance-modifying device (10) comprising a plurality of cells (15, 16), each cell comprising a plurality of charged particles (20) having a first polarity distributed in an optically transparent fluid (19), and first (17) and second (18) electrodes for enabling laterally displacing the particles (20) to concentrate the particles (20) at a first (54) and/or a second (46) particle concentration site through application of a voltage between the first (17) and second (18) electrodes, the second particle concentration site (46) having a larger particle concentration area than the first particle concentration site (45), the method comprising the steps of:
determining a voltage between the first (17) and second (18) electrodes resulting in an electric field configured to concentrate the particles (20) at the second particle concentration site (46); and
applying the voltage between the first (17) and second (18) electrodes to concentrate the particles (19) at the second particle concentration site (46).

11. The method according to claim 10, wherein, for each cell (15, 16: 31):
the cell (15, 16: 31) is defined by first (11 ) and second (12) substrates and a spacer structure (13) sandwiched between the first (11) and second (12) substrates;
the first electrode (17) is provided as a first electrode layer (17) formed on the first substrate (11), and the first particle concentration site (45) is defined by a recess formed in the dielectric layer (21); and
the second electrode (18) is separated from the first electrode layer (17) at least by the dielectric layer (21), the second particle concentration site (46) being determined by the second electrode (18).

12. A method for operating an appearance-modifying device (30) comprising a plurality of cells (31), each cell comprising a plurality of particles including a first set (20a) of charged particles having a first color and a first polarity, and a second set (20b) of charged particles having a second color and a second polarity, opposite the first polarity, distributed in an optically transparent fluid (19), and first (17) and second (18) electrodes for enabling laterally displacing the particles (20a, 20b) to concentrate the particles at a first (45) and/or a second (46) particle concentration site through application of a voltage between the first (17) and second (18) electrodes,
wherein each cell is configured in such a way that application between the first (17) and second (18) electrodes of a given voltage results in a first electric field adjacent to the first particle concentration site (45) and a second electric field adjacent to the second particle concentration site (46), the first electric field having a higher field strength than the second electric field, the method comprising the steps of:
determining a polarity and a magnitude of the voltage between the first (17) and second (18) electrodes resulting in that the first electric field is sufficiently strong to concentrate the first set of charged particles (20a) to the first electrode (17), and that the second electric field is so weak that the second set of particles (20b) substantially remain in a dispersed state; and
applying the determined voltage between the first (17) and second (18) electrodes to thereby control the cell (31) to a state having substantially the second color.

13. The method according to claim 12, wherein, for each cell (31):
the cell (31) is defined by first (11) and second (12) substrates and a spacer structure (13) sandwiched between the first (11) and second (12) substrates;
the first electrode (17) is provided as a first electrode layer (17) formed on the first substrate (11), and the first particle concentration site (45) is defined by a recess formed in the dielectric layer (21); and
the second electrode (18) is separated from the first electrode layer (17) at least by the dielectric layer (21), the second particle concentration site (46) being determined by the second electrode (18).
